(19) United States
(12) Patent Application Publication
(10) Pub. No.: US 2010/0012354 A1
(43) Pub. Date: Jan. 21, 2010

(54) THERMALLY CONDUCTIVE POLYMER BASED PRINTED CIRCUIT BOARD

(76) Inventors: Logan Brook Hedin, San Francisco, CA (US); David Michael Miller, Portola Valley, CA (US)

Correspondence Address: DERGOSITS & NOAH LLP, Three Embarcadero Center, Suite 410, SAN FRANCISCO, CA, 94111, US

(21) Appl. No.: 12/501,989

(22) Filed: Jul. 13, 2009

Related U.S. Application Data
(60) Provisional application No. 61/080,652, filed on Jul. 14, 2008.

(51) Int. Cl. H05K 1/00

(52) U.S. Cl. 174/252

(57) ABSTRACT

A printed circuit board has a liquid crystalline polymer layer that is bonded to an electrically conductive layer that includes traces that electrically connect components mounted on the printed circuit board. The liquid crystalline polymer material is thermally conductive and dielectric. When the components produce heat, the liquid crystalline polymer layer absorbs and dissipates the heat produced by the electrical components mounted on the printed circuit board. The thermal equilibrium of the printed circuit board is lower than the maximum operating temperature of the components.

### CROSS REFERENCE TO RELATED APPLICATIONS

This US Patent Application claims priority to U.S. Provisional Patent Applications No. 61/080,652, “Thermally Conductive Polymer Based Plastic Printed Circuit Board For Single Or Multilayer Applications (TCPPCB)” filed Jul. 14, 2008. U.S. Provisional Patent Application No. 61/080,652 is hereby incorporated by reference.

### FIELD OF INVENTION

The present invention relates to a printed circuit board apparatus and methods for making printed circuit boards.

### BACKGROUND

Printed circuit boards (PCBs) are used to mechanically support and electrically connect electronic components using conductive pathways, or traces, etched from metal sheets laminated onto a non-conductive substrate. In general, the non-conductive substrates have poor thermal conductivity properties. PCBs can have holes drilled for each wire or electrical connection of each component. The components' leads are passed through the holes and soldered to the traces. This method of assembly is called through-hole construction. Soldering of the components can be done automatically by passing the board over a ripple, or wave, of molten solder in a wave-soldering machine. The conductive layers are typically made of thin copper foil and the thermally insulating layers of dielectric materials are typically laminated together with epoxy resin prepreg.

Many electrical components generate heat. In order to dissipate the heat and keep the component cool, a heat sink with a higher heat capacity can be physically coupled to the electrical component. As the components generate heat, the thermal energy is transferred from the component to the heat sink which typically transfers the heat to the ambient air. This thermal energy transfer brings the electrical component into thermal equilibrium with the heat sink, lowering the temperature of the electrical component. The most common design of a heat sink is a metal device having many fins that increase the surface area of the heat sink. The high thermal conductivity of the heat sink and the large surface area allows the heat sink to rapidly transfer the thermal energy from the component to the surrounding air.

### SUMMARY OF THE INVENTION

The present invention is directed towards a thermally conductive PCB that dissipates heat from electrical components mounted on the PCB. Because the PCB dissipates the heat produced by the components, there is no need for separate heat sink to be attached to the heat producing electrical components. In an embodiment, the inventive PCB uses a thermally conductive polymer substrate that is bonded to an electrically conductive layer. The PCB can be fabricated in various different ways including: molding, lamination, conductive layer deposition, bonding, etc.

The conductive layer is preferably a low electrical resistance metal such as copper, silver, gold, aluminum, etc. The thermally conductive polymer is preferably, but not limited to, a liquid crystalline polymer (LCP) which is a relatively unique class of partially crystalline aromatic polyesters based on p-hydroxybenzoic acid and related monomers. Typically LCPs have outstanding mechanical properties including high temperature resistance, excellent chemical resistance and flame retardancy. In addition, LCPs have extremely low moisture absorption which provides for better processing, better dimensional stability, and reduces moisture related problems in board assembly and operation. A suitable LCP material is CoolPoly D5506 manufactured by CoolPolymers Inc. of Warwick, R.I.

The thermally conductive polymer should have a thermal conductivity of greater than 4 W/mK (watt/meter degree K.). Another important physical characteristic is the coefficient of thermal expansion (CTE). The thermal expansion must be low to prevent damage when the PCB is heated. In an embodiment, the coefficient of thermal expansion in the X and Y axes is lower than 18 ppm/° C. (part per million/degree C.) and the thermal expansion in the Z axis is less than 5% by volume over a temperature range of 50° C. to 260° C. By minimizing the thermal expansion, the physical dimensions of the PCB will not change significantly when the operating temperature of the PCB changes.

In addition to being thermally conductive, the thermally conductive polymer must be insulative. In a preferred embodiment, the dielectric constant of the thermally conductive polymer is less than 4.7 at a frequency of 1 megahertz. The electrical resistance of the polymer layer can also be measured by surface resistivity and volume resistivity. In a preferred embodiment, the thermally conductive polymer layer has a surface resistivity greater than 1×10³ megaohms and a volume resistivity greater than 1×10⁶ megaohms per cm when the polymer thickness is greater than 0.020 inch.

After the conductive layer is bonded to the polymer layer, to form the PCB, the conductive layer can be etched to form traces which are used to electrically connect the components that are mounted on the PCB. The traces can be formed by an etching process, a milling process or any other suitable means for selectively removing portions of the conductive layer. The traces are also drilled to form holes and the inner surfaces of the holes can be plated or a conductive ring or rivet can be inserted into the hole to form conductive vias in the PCB. When the PCB is completed, the electrical components are placed in the PCB and soldered to the vias and traces. The components can be soldered with a wave soldering mechanism. In order to prevent unwanted soldering, a solder mask can be used to protect areas of the PCB that do not require solder.

### BRIEF DESCRIPTION OF THE DRAWINGS

FIG. 1 is a cross section of a polymer based thermally conductive printed circuit board;

FIG. 2 is a cross section of a polymer based thermally conductive printed circuit board;

FIG. 3 is a view of a mold used to form a polymer based thermally conductive printed circuit board;

FIG. 4 is an extrusion machine forming a thermally conductive polymer substrate;

FIG. 5 illustrates a conductive layer laminated to a thermally conductive polymer substrate:

FIG. 6 is a cross sectional view of a CVD chamber;

FIG. 7 illustrates a cross sectional view of a PVC chamber;

FIGS. 8 and 9 illustrate an electrical trace formed on a conductive layer of a PCB;

FIG. 10 is a cross section of a polymer based thermally conductive printed circuit board; and

FIG. 11 and 12 illustrate heat transfer through a PCB having an array of LEDs.

### DETAILED DESCRIPTION

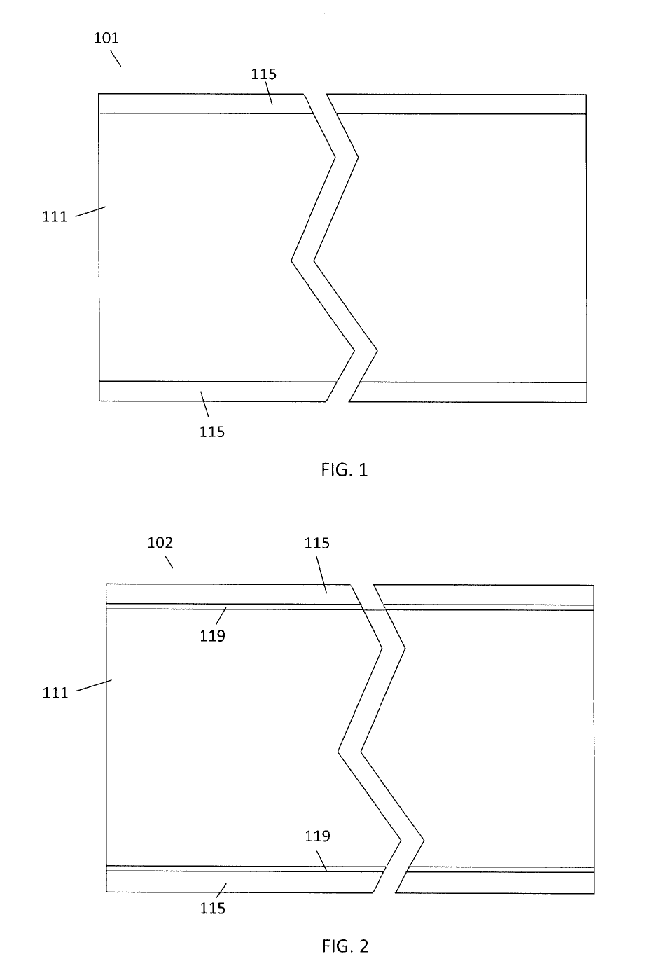

The present invention is directed towards a polymer based thermally conductive printed circuit board (PCB). With reference to FIG. 1 the PCB 101 includes a polymer substrate 111 and conductive layers 115 bonded to upper and lower surfaces of the polymer substrate 111. The present invention differs from the prior art because the polymer substrate 111 is a dielectric material that also has high thermal conductivity properties that help to dissipate heats from electrical components mounted on the PCB 101. This inherent ability to dissipate heat allows heat producing components to be mounted on the PCB 101 without the addition of a heat sink to keep the component at a thermal equilibrium that is within the acceptable operating temperature range. In this embodiment, the conductive layers 115 are bonded directly to the polymer substrate 111. In another embodiment with reference to FIG. 2, the PCB 102 uses layers of an adhesive bonding agent 119 can be used to bond the conductive layers 115 to the polymer substrate 111.

In a preferred embodiment, the polymer substrate 111 is a liquid crystalline polymer (LCP). Liquid-crystalline polymers are a class of aromatic polyester polymers that are dielectric, light weight, chemically inert and highly resistant to heat. The polymer substrate 111 preferably has specific physical properties including a high thermal conductivity and a high electrical resistance. The thermal conductivity of the polymer is preferably greater than 4 W/mK (watt/meter degree K.) and may be higher than 200 W/mK. The high thermal conductivity allows heat energy to be quickly transferred away from the electrical component and dissipated to the ambient air. The ability to transfer the heat energy to the air is related to the surface area of the polymer substrate 111. A large polymer substrate 111 will have more exposed surface area to transfer heat by convection to the surrounding air resulting in a lower temperature thermal equilibrium. In contrast, a smaller polymer substrate 111 will have a smaller convective surface area and a higher temperature thermal equilibrium. Thermal calculations should be performed to determine the proper geometry of the polymer substrate 111 so the thermal equilibrium temperature of the operating PCB will be within the design value range. Suitable liquid crystal polymer material is CoolPoly D5506 manufactured by CoolPolymers Inc. of Warwick, R.I.

A physical characteristic of heat is thermal expansion. As the PCB is heated it will tend to expand. This can be problematic because the rate of thermal expansion is typically different than the conductive layer and plating materials in the holes of the PCB. When the PCB is heated, the dimensional differences due to thermal expansion can result in damage such as cracking of the conductive layer and cracking of the conductive plating in the via holes. In order to minimize this problem, the thermal expansion of the polymer substrate 111 is minimized.

In a preferred embodiment, the coefficient of thermal expansion (CTE) is preferably less than 18 ppm/° C. (part per million/degree C.) in the X axis and the Y axis which extend along the width and length of the polymer substrate 111 layer. The Z axis extends in the direction of the thickness of the polymer substrate 111 layer. In a preferred embodiment, the thermal expansion in the Z axis is less than 5% by volume over the temperature range 50° C. to 260° C. and possibly less than 1% by volume.

The polymer substrate 111 should also have a low dielectric value and a high electrical resistance. In a preferred embodiment, the dielectric constant of the polymer substrate 111 is less than 4.7 at a frequency of 1 Megahertz and may be lower than 2.1. The resistivity of the polymer substrate 111 can be measured in different ways. A volume resistivity is the ratio of the dc voltage drop per unit thickness to the amount of current per unit area passing through the polymer substrate 111 material. In a preferred embodiment, the resistivity of the polymer substrate 111 is greater than 1×10⁶ megaohms-cm and can be greater than 1×10⁹ megaohms-cm when the thickness of the polymer layer 111 is greater than 0.020 inches when tested in accordance to The Institute for Interconnecting and Packaging Electronic Circuits, IPC test method 2.5.17.1. Another way to measure the resistivity is by the surface resistivity which is the ratio of the dc voltage drop per unit length to the surface current per unit width for electric current flowing across the polymer substrate 111 surface. In a preferred embodiment, the surface resistivity is greater than 1×10³ megaohms and may be greater than 1×10⁸ megaohms when the thickness of the polymer layer is greater than 0.020 inches when surface resistivity is measured in accordance with The Institute for Interconnecting and Packaging Electronic Circuits, IPC test method 2.5.17.1 Because the polymer material is thermally conductive and electrically insulative, the inventive PCB has better thermal performance characteristics than other substrate materials. A suitable liquid crystal polymer material is CoolPoly D5506 manufactured by CoolPolymers Inc. of Warwick, R.I.

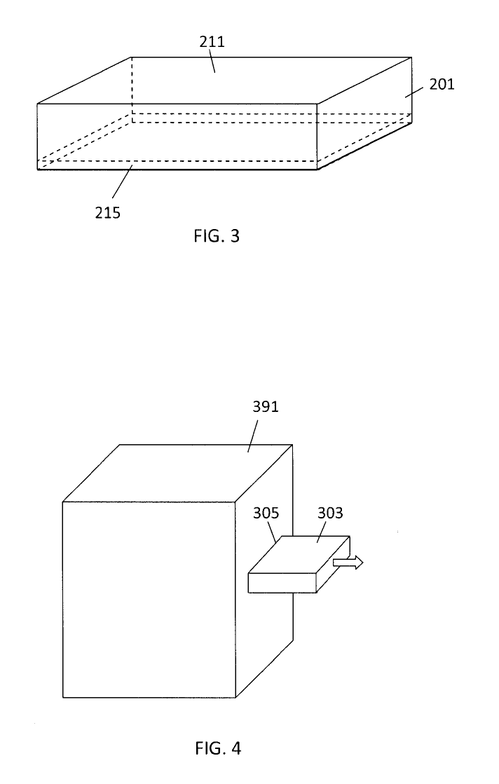

The conductive layer 115 material is preferably a highly conductive metal such as copper, silver or gold. The conductive layer 115 can be attached to the polymer substrate 111 in many different ways. In an embodiment, the conductive layer 115 is co-molded with the polymer substrate 111. In this embodiment with reference to FIG. 3, the conductive layer 215 can be placed into a mold 201. The polymer 211 can be heated to a liquid state and injected into the mold 201. The polymer 211 is then cooled so the polymer solidifies in the mold 201 to form the polymer substrate 211. Since the polymer 211 solidifies while in contact with the conductive layer 215, this causes the polymer substrate 211 to bond to the conductive layer 215 without a separate bonding agent. The mold 201 is disassembled to remove the PCB.

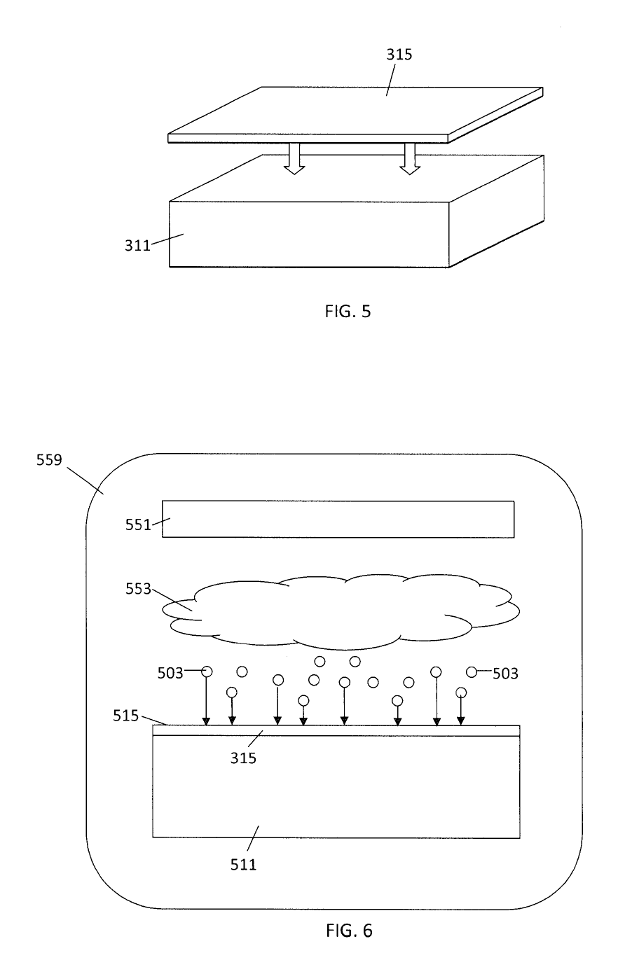

In another embodiment with reference to FIGS. 4 and 5, the PCB can be formed through extrusion and lamination processes. The liquid polymer 303 can be extruded to form the polymer substrate 311 and then laminated to the conductive layer 315. In this embodiment, the thermally conductive plastic is heated and pressurized to force the liquid polymer 303 material through a die 305 in an extrusion machine 391 to create a polymer substrate 311. With reference to FIG. 5, after the liquid polymer 303 is extruded through the die 305, it is cut to the desired length and laminated to the electrically conductive layer 315 to physically bond the two materials together. The bonding can be due to the solidification of the liquid polymer 303 while in contact with the conductive layer 315 or a bonding agent can be used to laminate the conductive layer 315 to the polymer substrate 311. In an embodiment, heat and pressure can be applied to laminate the conductive layer 315 to the polymer substrate 311.

In another embodiment, the conductive layer can be plated onto the polymer substrate 111 by creating an atomic bond between the electrically conductive layer and the thermally conductive polymer based plastic substrate. This can be achieved by means such as chemical vapor deposition (CVD) or physical vapor deposition (PVD). With reference to FIG. 6, in CVD processing chamber 559 is illustrated, the polymer layer substrate 511 is exposed to one or more volatile precursors 503, which react and decompose on the polymer layer substrate 511 surface to produce the conductive layer 515. In an embodiment, an electrode 551 is used to generate a plasma 553 which vaporizes the precursors 503 that are then deposited on the polymer substrate 511 to form the conductive layer 515. Once the desired layer thickness is deposited, the process is stopped and the PCB is removed from the chamber 559.

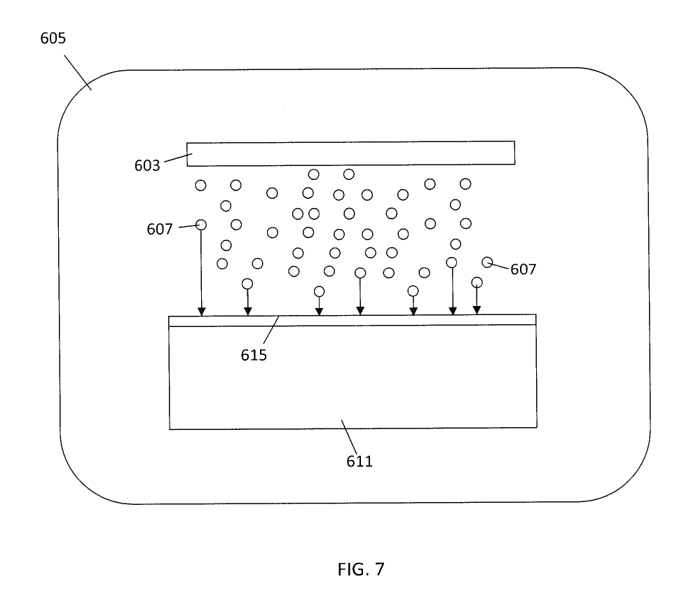

With reference to FIG. 7, a PVD processing chamber 605 is illustrated. PVD vaporizes the conductive material and the vapors condense on the polymer layer substrate to form the conductive layer. The formation of the conductive layer involves purely physical processes. The conductive target material 603 is heated to its boiling point in the vacuum chamber 605. The conductive material 603 can be heated by resistance heating, electron beam, or plasma. The vaporized conductive material 607 is then removed from the target material 603 and deposited on a surface polymer substrate 601. The vaporized conductive materials 607 then solidify to form the conductive metal layer 615 on the polymer substrate 611. After the conductive layer reaches the desired thickness, the process is stopped and the PCB is removed from the chamber 605.

In other embodiments, electroplating or electroless plating methods can be used to form the conductive layer. Since the conductive layer is typically a metal material, a metalizing process can be used that deposits a layer of metal on the surface of non-metallic objects. Because a non-metallic object tends to be poor electrical conductors, the surface of the polymer substrate may require a sequence of processing steps before the metal plating can be performed. In an embodiment, the polymer substrate 111 is etched by a sequence of chemical processes, including: a hot chromic acid-sulfuric acid mixture, a tin(II) chloride solution, and a palladium chloride solution. The processed surface can then be coated with the desired metal material such as electroless copper plating to form the conductive layer.

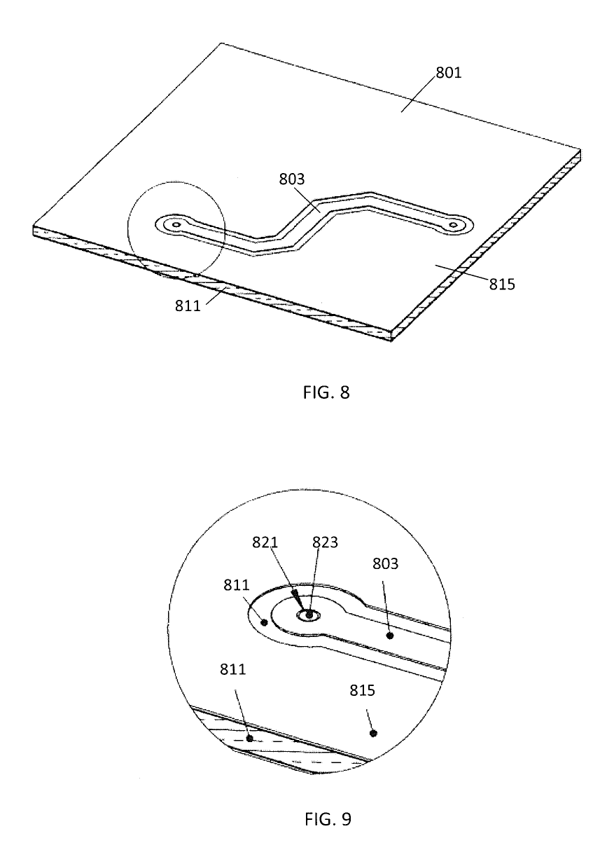

With reference to FIG. 8, after the conductive layer 815 is bonded to the polymer substrate 811, the traces 803 are formed on the conductive layer 815. The traces 803 are the electrically conductive paths between the different components mounted on the PCB 801. The traces 803 can be formed in various ways. In an embodiment, the traces 803 are formed by removing portions of the conductive layer 815. A patterned mask layer is deposited over the traces 803 and other areas of the conductive layer 815 that should remain. The patterned mask can be formed by silk screen printing or other suitable methods such as photolithography. An etch process is then applied which removes the portions of the conductive layer that are not covered by the mask and forms the traces 803. After etching, the mask layer is removed.

In another embodiment, traces 803 can be formed by a milling process that uses a two or three-axis mechanical milling system to mill away portions of the conductive layer from the polymer substrate. The milling machine can receive software commands that control the position of the milling head in the x, y, and (if relevant) z axis to form the traces 803 in the conductive layer 815. Because each PCB 801 is formed individually, very small runs of different PCB designs can be created efficiently using the milling process.

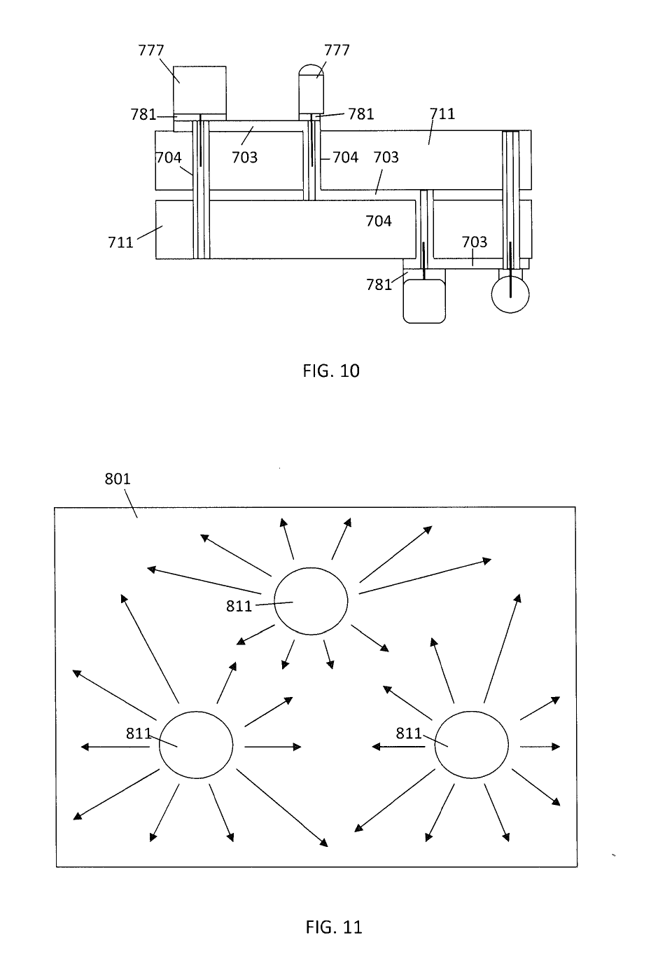

In the illustrated embodiment, the conductive layer 815 is a copper metal material and a thin area of the conductive layer 815 around the trace 803 has been etched to separate the trace 803 from the rest of the conductive layer 815. Vias 823 are formed in the PCB 801 at the ends of the trace 803. With reference to FIG. 9, a more detailed illustration of a via 823 is illustrated. The vias 823 are formed by drilling a hole through the PCB 801 at the end of the trace 803. The drilling can be performed by automated drilling machines that can be controlled by computer-generated files are also called numerically controlled drill (NCD) files. In other embodiments, the holes can be formed in the PCB by laser drilling. The drill files can describe the location and size of each drilled hole. These holes are then filled with electrically conductive annular rings or plated with a conductive material to create vias 823 that allow the leads of the electrical components to mounted on the PCBs. The conductive material in the via 823 extends through the PCB 801 and can be in electrical contact with the conductive layer on the opposite side of the PCB 801.

In other embodiments, the traces can be formed through different processes. For example, a reverse mask can be applied to the thin conductive layer which covers areas where the conductive material will be removed. Additional conductive material is then plated onto the PCB in the unmasked areas to the desired thickness. The mask is then stripped away and a brief etching process removes the original thin conductive material from the PCB forming the pattern of traces.

After the PCB is completed, the leads of the electrical components can be placed through the designated holes and soldered into place to form required electrical connections. Soldering of the components can be done automatically by passing the inventive PCB over a ripple, or wave, of molten solder in a wave-soldering machine. In order to prevent soldering in areas that should not be soldered, portions of the PCB may be covered with a polymer solder resist (solder mask) coating during the PCB fabrication process. The solder resist can be very useful in preventing solder from bridging between adjacent traces and thereby creating short circuits.

The inventive PCB has been described as a single layer board. However, it can also be used with multiple layer PCBs. With reference to FIG. 10, a multiple layer PCB 701 is illustrated. The PCB 701 includes multiple polymer substrate layers 711 and traces 703 formed on the exposed surfaces of the PCB 701 and between the layers 711. In order to electrically connect the components on the different layers 711, the conductive vias 704 can electrically connect traces 703 on opposite sides of the polymer substrate 707. This allows components 777 mounted on either side of the multi layered PCB 701 to be electrically connected.

When electricity is applied to the PCB circuit, the components 777 operate and emit heat. The heat energy is transferred by convection through the exposed surfaces of the components 777 to the ambient air. The heat also conducts from the electrical leads to the traces 703 and the polymer layer 711. In an embodiment, the thermal conduction from the components 777 to the PCB 801 is improved by a layer of thermal grease 781 that is placed between the components 777 and the PCB 701. The thermal grease 781 has high thermal conductivity and also increases the contact area or thermal interface between the components 777 and the PCB 701. Thus, the heat emitted by the components 777 can flow more easily into the PCB 701. Various thermal greases are available including: ceramic based and carbon based. These thermal greases are usually composed of a ceramic powder or carbon suspended in a liquid or gelatinous silicone compound.

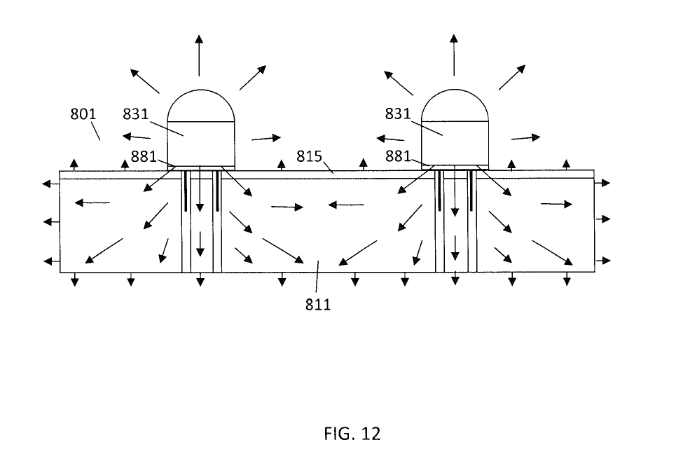

The inventive PCB is suitable for many real world applications and is compatible with all manner of electronic devices that currently use conventional printed circuit boards and have a need for board level thermal dissipation or transfer. With reference to FIGS. 11 and 12, a specific example of a heat producing application is illustrated. The inventive thermally conductive PCB 801 is being used as the base material for an LED lighting array. The LEDs 831 can be soldered onto the PCB 801 to form a circuit that illuminates the array of LEDs 811 for lighting purposes. In addition to light, the LEDs 831 give off heat which requires thermal dissipation or transfer of heat away from the LEDs 831. Some of the heat from the LEDs 831 is transferred by convection to the ambient air but most of the heat energy flows through the thermal grease 781 and the conductive layer 815 to the thermally conductive polymer layer 811 of the PCB 801 as illustrated by the arrows directed away from the LEDs 831.

The heat energy then flows through the polymer layer 811 to the exposed areas of the PCB 801 to the ambient gas. The rate of heat transfer from the PCB 801 is related to differential temperature of the ambient gas. If the ambient air is significantly cooler than the PCB 801, a higher rate of heat energy is transferred from the PCB 801 to the surrounding air by convective heat transfer. The rate of convective heat transfer from the PCB 801 can also be enhanced by air flow which can be caused by a fan or rising hot air.

The described PCBs have included vias that are used to connect the components to the PCB. However, in other embodiments vias are not required. For example, the inventive PCBs can be used for surface-mount components (SMCs) or surface-mount devices (SMDs). Rather than placing the electrical leads of the components through the vias, electrical tabs are soldered directly to the traces in the electrically conductive layer of the PCB. The PCB can have conductive pads without holes, called solder pads. Solder paste which is a mixture of flux and tiny solder particles, is first applied to all of the solder pads using a screen printing process. After screen printing, pick-and-place machines place the electrical components on the PCB. The PCBs are then conveyed into a reflow soldering oven that gradually heats the PCBs and components until the solder particles melt in the solder paste, bonding the component leads to the pads on the circuit board.

In many applications, the thermal heat transfer of the inventive PCB enhances the thermal management of the associated electrical circuit without requiring additional heat sink components. No other PCB base material at this time is made using a polymerized plastic which is both electrically insulative and thermally conductive, thus opening new horizons of possibility in circuit design.

It will be understood that the inventive system has been described with reference to particular embodiments, however additions, deletions and changes could be made to these embodiments without departing from the scope of the inventive system. Although the CMP systems that have been described include various components, it is well understood that these components and the described configuration can be modified and rearranged in various other configurations.

What is claimed is:

1. A printed circuit board comprising:
a thermally conductive dielectric polymer layer; and
a first electrically conductive layer having a first set of traces bonded to the thermally conductive dielectric polymer layer.

2. The printed circuit board of claim 1 further comprising:
a bonding agent layer between the electrically conductive layer and the polymer layer for bonding the electrically conductive metal layer to the polymer layer.

3. The printed circuit board of claim 1 further comprising:
a plurality of vias in the printed circuit board that are electrically coupled to the traces and further extend at least partially through the thermally conductive dielectric polymer layer.

4. The printed circuit board of claim 1 wherein the thermally conductive dielectric polymer layer comprises partially crystalline aromatic polyesters.

5. The printed circuit board of claim 1 wherein the thermally conductive dielectric polymer layer has a thermal conductivity greater than 4 W/mK.

6. The printed circuit board of claim 1 wherein the thermally conductive dielectric polymer layer has a coefficient of thermal expansion less than 18 ppm/degree Celsius in the X and Y axis directions.

7. The printed circuit board of claim 1 wherein the thermally conductive dielectric polymer layer has a dielectric constant is less than 4.7 at a frequency of 1 megahertz.

8. The printed circuit board of claim 1 wherein the thermally conductive dielectric polymer layer has a volume resistivity greater than 1×10⁶ megaohms per centimeter.

9. The printed circuit board of claim 1 wherein the thermally conductive dielectric polymer layer has a surface resistivity greater than 1×10³ megaohms.

10. A thermally conductive printed circuit board comprising:
a thermally conductive liquid crystalline polymer layer; and
an electrically conductive layer having a first set of patterned electrical traces bonded to the liquid crystalline polymer layer.

11. The printed circuit board of claim 10 further comprising:
a bonding agent layer between the electrically conductive layer and the polymer layer for bonding the electrically conductive metal layer to the polymer layer.

12. The printed circuit board of claim 10 further comprising:
a plurality of vias that are electrically coupled to the traces and extend at least partially through the thermally conductive dielectric polymer layer.

13. The printed circuit board of claim 10 wherein the thermally conductive liquid crystalline polymer layer comprises partially crystalline aromatic polyesters based on a p-hydroxybenzoic acid and related monomers.

14. The printed circuit board of claim 10 wherein the liquid crystalline polymer layer has a thermal conductivity greater than 4 W/mK.

15. The printed circuit board of claim 10 wherein the liquid crystalline polymer layer has a coefficient of thermal expansion range less than 18 ppm/degree Celsius in the X and Y axis directions.

16. The printed circuit board of claim 10 wherein the liquid crystalline polymer layer has a dielectric constant less than 4.7 at a frequency of 1 Megahertz.

17. The printed circuit board of claim 10 wherein the liquid crystalline polymer layer has a volume resistivity greater than 1×10⁶ megaohms centimeter.

18. The printed circuit board of claim 10 wherein the liquid crystalline polymer layer has a surface resistivity is greater than 1×10³ megaohms.

19. A printed circuit board comprising:
a first dielectric thermally conductive liquid crystalline polymer layer;
a first electrically conductive layer having a first pattern of electrical traces bonded to a first side of the first dielectric thermally conductive liquid crystalline polymer layer; and
a second electrically conductive layer having a second pattern of electrical traces bonded to a second side of the first dielectric thermally conductive liquid crystalline polymer layer.

20. The printed circuit board of claim 19 further comprising:
a second dielectric thermally conductive liquid crystalline polymer layer; and
a third electrically conductive layer having a third pattern of electrical traces bonded to a second side of the second dielectric thermally conductive liquid crystalline polymer layer; wherein the second electrically conductive layer is bonded to a first side of the second dielectric thermally conductive liquid crystalline polymer layer.
